(19) United States
(12) Patent Application Publication
(10) Pub. No.: US 2026/0107670 A1
(43) Pub. Date: Apr. 16, 2026

(54) DISPLAY DEVICE AND ELECTRONIC DEVICE

(71) Applicant: Samsung Display Co., LTD., Yongin-si (KR)

(72) Inventors: Eun Byul KIM, Yongin-si (KR); Han Bum KWON, Yongin-si (KR); Young Min AHN, Yongin-si (KR); Kyung Bin CHOI, Yongin-si (KR)

(21) Appl. No.: 19/220,847

(22) Filed: May 28, 2025

(30) Foreign Application Priority Data
Oct. 15, 2024 (KR) 10-2024-0140257

(51) Int. Cl. H10K 59/88; H10K 59/131; H10K 59/80; H10K 102/00

(52) U.S. Cl. CPC H10K 59/88; H10K 59/1315; H10K 59/871; H10K 2102/3026

(57) ABSTRACT

A display device includes a first pad electrode on a substrate in a pad area of the substrate, a second pad electrode on the first pad electrode, a first support unit between the first pad electrode and the second pad electrode, an alignment mark on the substrate in the pad area, and a second support unit on the alignment mark.

This application claims priority to Korean Patent Application No. 10-2024-0140257, filed on Oct. 15, 2024, and all the benefits accruing therefrom under 35 U.S. C. § 119, the content of which in its entirety is herein incorporated by reference.

### BACKGROUND

### 1. Field

The disclosure generally relates to a display device and an electronic device.

### 2. Related Art

Recently, as interest in information displays is increased, research and development of display devices have been continuously conducted.

### SUMMARY

Embodiments provide a display device in which a defect due to bonding stress of a display panel and a driving unit is effectively prevented.

In accordance with an embodiment of the disclosure, a display device includes: a first pad electrode on a substrate in a pad area of the substrate; a second pad electrode on the first pad electrode; a first support unit between the first pad electrode and the second pad electrode; an alignment mark on the substrate in the pad area; and a second support unit on the alignment mark.

In an embodiment, the first support unit may be disposed in a same layer as the second support unit.

In an embodiment, a thickness of the first support unit may be substantially the same as a thickness of the second support unit.

In an embodiment, the first support unit may include a same material as the second support unit.

In an embodiment, each of the first support unit and the second support unit may include an organic material.

In an embodiment, the display device may further include a driving terminal electrically connected to the second pad electrode.

In an embodiment, the second pad electrode may be in contact with the driving terminal.

In an embodiment, the second pad electrode may be disposed between the first support unit and the driving terminal.

In an embodiment, the display device may further include an adhesive layer between the second pad electrode and the driving terminal.

In an embodiment, the second support unit may be disposed between the alignment mark and the driving terminal.

In accordance with another embodiment of the disclosure, a display device includes: a first pad electrode on a substrate in a pad area of the substrate; a second pad electrode on the first pad electrode; a first support unit between the first pad electrode and the second pad electrode; an alignment mark on the substrate in the pad area; and a third support unit on the substrate at a periphery of the alignment mark.

In an embodiment, the third support unit may not overlap the alignment mark in a plan view.

In an embodiment, the first support unit may be disposed in a layer different from a layer in which the third support unit is disposed.

In an embodiment, a thickness of the third support unit may be greater than a thickness of the first support unit.

In an embodiment, each of the third support unit and the first support unit may include an organic material.

In an embodiment, the display device may further include a driving terminal electrically connected to the second pad electrode.

In an embodiment, the second pad electrode may be in contact with the driving terminal.

In an embodiment, the second pad electrode may be disposed between the first support unit and the driving terminal.

In an embodiment, the display device may further include an adhesive layer between the second pad electrode and the driving terminal.

In an embodiment, the third support unit may not overlap the driving terminal in a plan view.

In accordance with an embodiment of the disclosure, an electronic device includes: a processor which provides input image data; and a display device which displays an image based on the input image data, where the display device includes: a first pad electrode on a substrate in a pad area of the substrate; a second pad electrode on the first pad electrode; a first support unit between the first pad electrode and the second pad electrode; an alignment mark on the substrate in the pad area; and a second support unit on the alignment mark.

### BRIEF DESCRIPTION OF THE DRAWINGS

The above and other features of embodiments of the invention will become more apparent by describing in further detail embodiments thereof with reference to the accompanying drawings.

FIG. 1 is a side view schematically illustrating a display device in an embodiment of the disclosure.

FIG. 2 is a plan view schematically illustrating a display panel in an embodiment of the disclosure.

FIG. 3 is a plan view schematically illustrating a pixel in an embodiment of the disclosure.

FIG. 4 is a sectional view taken along line I-I′ shown in FIG. 3.

FIGS. 5 to 7 are plan views schematically illustrating a portion of a pad area in an embodiment of the disclosure.

FIG. 8 is a sectional view taken along line A-A′ shown in FIG. 5.

FIG. 9 is a sectional view taken along line B-B′ shown in FIG. 5.

FIG. 10 is a sectional view taken along line C-C′ shown in FIG. 5.

FIG. 11 is a block diagram of an electronic device according to an embodiment.

FIG. 12 shows schematic views of various embodiments of an electronic device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

It will be understood that when an element is referred to as being “on” another element, it can be directly on the other element or intervening elements may be present therebetween. In contrast, when an element is referred to as being “directly on”another element, there are no intervening elements present.

In the entire specification, when an element is referred to as being “connected” or “coupled” to another element, it can be directly connected or coupled to the another element or be indirectly connected or coupled to the another element with one or more intervening elements interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from X, Y, and Z” can be construed as X only, Y only, Z only, or any combination of two or more items X, Y, and Z (e.g., XYZ, XYY, YZ, ZZ).

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

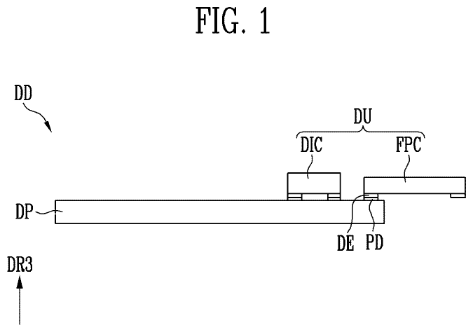

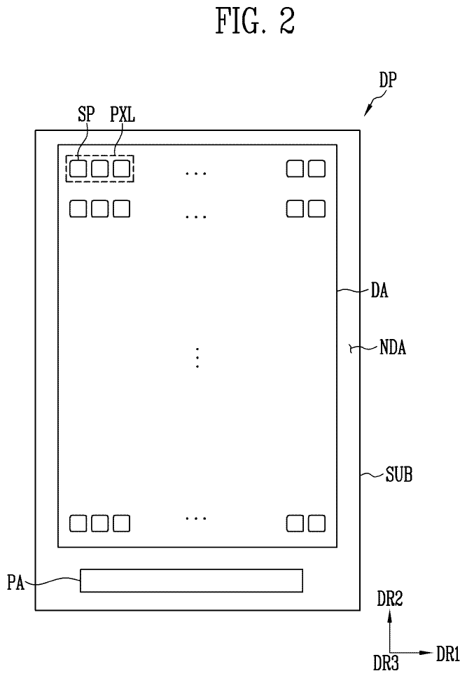

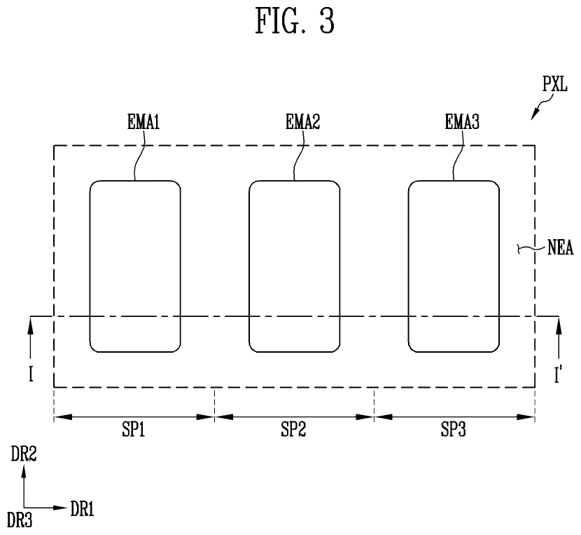

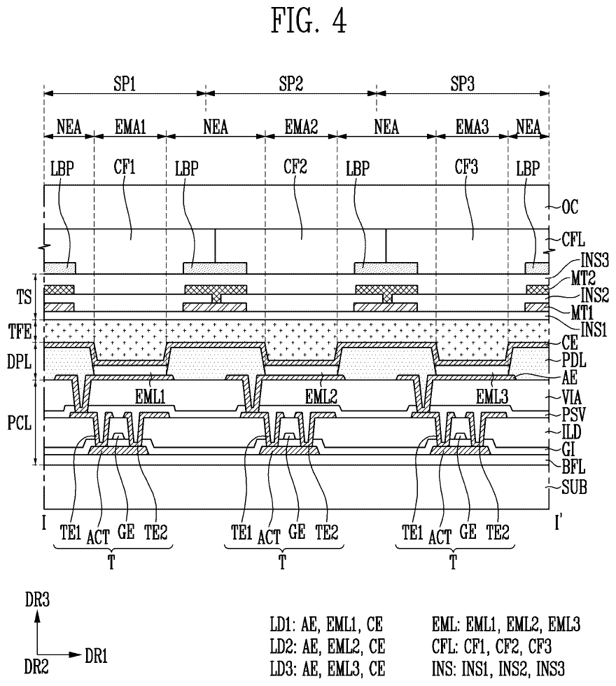

FIG. 1 is a side view schematically illustrating a display device in an embodiment of the disclosure. FIG. 2 is a plan view schematically illustrating a display panel in an embodiment of the disclosure. FIG. 3 is a plan view schematically illustrating a pixel in an embodiment of the disclosure. FIG. 4 is a sectional view taken along line I-I′ shown in FIG. 3.

Referring to FIGS. 1 to 4, an embodiment of a display device DD may include a display panel DP and a driving unit DU.

The display device DD may be applied to electronic devices such as a smart phone, a computing system, a display system, smart glasses, a head-mounted display (HMD), and a vehicle display device.

The display device DD may have various shapes. The display device DD may have a closed-loop shape including linear sides and/or curved sides. In an embodiment, for example, the display device DD may have one of various shapes such as a polygon, a circle, a semicircle, and an ellipse.

The display device DD may have a flat display surface. Alternatively, the display device DD may at least partially have a round display surface. In an embodiment, the display device DD may be bendable, foldable or rollable. The display device DD (or the display panel DP) may include materials having flexibility.

The display panel DP may be implemented as an organic light emitting display (OLED) panel using an organic light emitting diode as a light emitting element, a micro-light emitting diode (LED) or nano-LED display panel using a micro-LED or nano-LED as a light emitting element, a quantum dot (QD) OLED panel using a quantum dot and an organic light emitting diode, or the like. However, the disclosure is not necessarily limited thereto.

In an embodiment, as shown in FIG. 2, the display panel DP may include a display area DA and a non-display area NDA. The display panel DP may display an image through the display area DA. The non-display area NDA may be disposed at the periphery of the display area DA.

The display panel DP may include a substrate SUB, sub-pixels SP, and/or a pad area PA. The sub-pixels SP may be disposed in the display area DA on the substrate SUB. The sub-pixels SP may be arranged in a matrix form along a first direction DR1 and a second direction DR2 intersecting the first direction DR1. However, embodiments are not limited thereto. In an embodiment, for example, the sub-pixels SP may be arranged in a zigzag form along the first direction DR1 and the second direction DR2. In an embodiment, for example, the sub-pixels SP may be arranged in a PENTILE™ form. The first direction DR1 may be a row direction, and the second direction DR2 may be a column direction. Here, a third direction, which is perpendicular to the first direction DR1 and the second direction DR2 may be a thickness direction of the display panel DP. Here, “in a plan view” may means “when viewed in the third direction DR3.” Two or more sub-pixels among the sub-pixels SP may constitute or collective defined one pixel PXL.

A component for controlling the sub-pixels SP may be disposed in the non-display area NDA on the substrate SUB. In an embodiment, for example, lines, such as gate lines and data lines, connected to the sub-pixels SP may be disposed in the non-display area NDA.

The pad area PA may be disposed in the non-display area NDA on the substrate SUB. Pads PD may be disposed in the pad area PA. The pads PD may be electrically connected to the sub-pixels SP through the lines. In an embodiment, for example, the pads PD may be connected to the sub-pixels SP through the data lines.

In an embodiment, as shown in FIG. 1, the pads PD may be electrically connected to the driving unit DU. In an embodiment, voltages and signals, which are used for operations of components included in the display panel DP, may be provided from the driving unit DU through the pads PD. The driving unit DU may include a driving integrated circuit DIC and/or a flexible circuit board FPC. The driving integrated circuit DIC and the flexible circuit board FPC may be electrically connected to each other.

Driving terminals DE may be disposed under the driving integrated circuit DIC. The driving terminals DE may be electrically connected to the pads PD. The driving terminals DE may be directly connected to the pads PD. In an embodiment, an adhesive layer may be disposed between the driving terminals DE and the pads PD. The adhesive layer may be a non-conductive film (NCF), but the disclosure is not necessarily limited thereto.

The display area DA may have one of various shapes. The display area DA may have a closed-loop shape including linear sides and/or curved sides. In an embodiment, for example, the display area DA may have one of various shapes such as a polygon, a circle, a semicircle, and an ellipse.

In an embodiment, the display panel DP may have a flat display surface. Alternatively, the display panel DP may have at least partially round display surface. In an embodiment, the display panel DP may be bendable, foldable or rollable. The display panel DP and/or the substrate SUB may include materials having flexibility.

In an embodiment, as shown in FIG. 3, a pixel PXL may include first to third sub-pixels SP1 to SP3 arranged in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

The first emission area EMA1 may be an area in which light is emitted from a first light emitting layer EML1 of the first sub-pixel SP1. The second emission area EMA2 may be an area in which light is emitted from a second light emitting layer EML2 of the second sub-pixel SP2. The third emission area EMA3 may be an area in which light is emitted from a third light emitting layer EML3 of the third sub-pixel SP3.

In an embodiment, as shown in FIG. 4, each of the first to third sub-pixels SP1 to SP3 may include a pixel circuit layer PCL, a display element layer DPL, and/or a thin film encapsulation layer TFE, which are sequentially disposed on the substrate SUB.

The substrate SUB may form a base surface. The substrate SUB may include a transparent insulating material to allow light to be transmitted therethrough. The substrate SUB may be a rigid substrate or a flexible substrate.

The pixel circuit layer PCL may include a pixel circuit provided on the substrate SUB. The pixel circuit layer PCL may include a buffer layer BFL, a gate insulating layer GI, an interlayer insulating layer ILD, a passivation layer PSV, and/or a via layer VIA, which are sequentially stacked on the substrate SUB in the third direction DR3.

The buffer layer BFL may be an inorganic insulating layer including an inorganic material. The buffer layer BFL may include at least one selected from silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer, but be provided as a multi-layer including at least two layers. In an embodiment where the buffer layer BFL is provided as the multi-layer, the layers in the buffer layer BFL may include or be formed of a same material as each other or be formed of different materials from each other. The buffer layer BFL may be omitted according to a material of the substrate SUB, a process condition, or the like.

A transistor T may be disposed on the buffer layer BFL. The transistor T may include an active pattern ACT, a gate electrode GE, a first transistor electrode TE1, and/or a second transistor electrode TE2.

The active pattern ACT may be disposed on the buffer layer BFL. The active pattern ACT may include a poly-silicon semiconductor. In an embodiment, for example, the active pattern ACT may be formed through a low temperature poly-silicon process. However, the disclosure is not necessarily limited thereto, and the active pattern ACT may include or be formed of an oxide semiconductor, a metal oxide semiconductor, or the like.

The active pattern ACT may include a channel region, a first contact region connected to one end of the channel region, and a second contact region connected to another end of the channel region. The channel region, the first contact region, and the second contact region may be formed with a semiconductor layer undoped or doped with an impurity. In an example, the first contact region and the second contact region may be formed with a semiconductor layer doped with the impurity, and the channel region may be formed with a semiconductor layer undoped with the impurity. A p-type impurity may be used as an example of the impurity, but the disclosure is not limited thereto. One of the first and second contact regions may be a source region, and the other of the first and second contact regions may be a drain region.

The gate insulating layer GI may be disposed over the active pattern ACT. The gate insulating layer GI may be an inorganic layer (or inorganic insulating layer) including an inorganic material. In an embodiment, for example, the gate insulating layer GI may include at least one selected from silicon nitride (SiNₓ), silicon oxide (SiOₓ), silicon oxynitride (SiOₓN_{y}), and a metal oxide such as aluminum oxide (AlOₓ). However, the material of the gate insulating layer GI is not limited to the above-described embodiments. In some embodiments, the gate insulating layer GI may be an organic layer (or organic insulating layer) including an organic material. The gate insulating layer GI may be provided as a single layer, or be provided as a multi-layer including at least two layers.

The gate electrode GE may be disposed on the gate insulating layer GI. The gate electrode GE may overlap a channel region of the active pattern ACT in the third direction DR3 (or when viewed in a plan view). The gate electrode GE may be provided as (or defined by) a single layer, using one selected from copper (Cu), molybdenum (Mo), tungsten (W), aluminum neodymium (AlNd), titanium (Ti), aluminum (Al), and silver (Ag), or a mixture thereof, or be formed in a double-layer or multi-layer structure including molybdenum (Mo), titanium (Ti), copper (Cu), aluminum (Al), and silver (Ag), which are low resistance materials, to reduce wiring resistance.

The interlayer insulating layer ILD may be disposed over the gate electrode GE. The interlayer insulating layer ILD may include a same material as the gate insulating layer GI, or include at least one material selected from the materials listed above as the material constituting the gate insulating layer GI.

The first transistor electrode TE1 and the second transistor electrode TE2 may be disposed on the interlayer insulating layer ILD. The first transistor electrode TE1 of the transistor T may be in contact with the first contact region of the active pattern ACT through a contact hole defined or formed through the interlayer insulating layer ILD and the gate insulating layer GI. In an embodiment, the first contact region is the source region, and the first transistor electrode TE1 may be a first source electrode.

The second transistor electrode TE2 of the transistor T may be in contact with the second contact region of the other end of the active pattern ACT through a contact hole defined or formed through the interlayer insulating layer ILD and the gate insulating layer GI. When the second contact region is the drain region, the second transistor electrode TE2 may be a second drain electrode.

Each of the first transistor electrode TE1 and the second transistor electrode TE2 may include a same material as the gate electrode GE, or include at least one material selected from the materials listed above as the material constituting the gate electrode GE.

The passivation layer PSV may be disposed over the first transistor electrode TE1 and the second transistor electrode TE2. The passivation layer PSV (e.g., a protective layer) may be an inorganic layer (or inorganic insulating layer) including an inorganic material or an organic layer (or organic insulating layer) include an organic material. The inorganic layer may include, for example, at least one selected from silicon nitride (SiNₓ), silicon oxide (SiOₓ), silicon oxynitride (SiOₓN_{y}), and a metal oxide such as aluminum oxide (AlOₓ). The organic layer may include, for example, at least one selected from acrylic resin, epoxy resin, phenolic resin, polyamide resin, polyimide resin, unsaturated polyester resin, poly-phenylene ether resin, poly-phenylene sulfide resin, and benzocyclobutene resin.

In some embodiments, the passivation layer PSV may include the same material as the interlayer insulating layer ILD, but the disclosure is not limited thereto. The passivation layer PSV may be provided as a single layer, but be provided as a multi-layer including at least two layers.

The via layer VIA may be disposed on the passivation layer PSV. The via layer VIA may include a same material as the passivation layer PSV, or include at least one material selected from the materials listed above as the material constituting the passivation layer PSV. In an embodiment, the via layer VIA may be an organic layer made of an organic material.

The display element layer DPL may be disposed on the pixel circuit layer PCL. The display element layer DPL may include a light emitting element LD emitting light. The first to third sub-pixels SP1 to SP3 may include first to third light emitting elements LD1 to LD3, respectively.

The first light emitting element LD1 may include an anode electrode AE, a first light emitting layer EML1, and a cathode electrode CE. The second light emitting element LD2 may include an anode electrode AE, a second light emitting layer EML2, and the cathode electrode CE. The third light emitting element LD3 may include an anode electrode AE, a third light emitting layer EML3, and the cathode electrode CE. In an embodiment, for example, each of the first to third light emitting elements LD1 to LD3 may be a top-emission organic light emitting element, as shown in FIG. 4.

The anode electrode AE of each sub-pixel SP may be disposed in an emission area EMA, and the anode electrodes AE of the sub-pixels SP may be spaced apart from each other. The anode electrode AE of each sub-pixel SP may be electrically connected to a first transistor electrode TE1 of a transistor T of each sub-pixel SP through a contact hole defined or formed through the via layer VIA and the passivation layer PSV.

A bank PDL may be disposed on the anode electrode AE. The bank PDL may define (or partition) an emission area EMA of each sub-pixel SP. The bank PDL may define an opening partially exposing the anode electrode AE of each sub-pixel SP.

The bank PDL may be an organic insulating layer including or made of an organic material. The organic material may include at least one selected from acrylic resin, epoxy resin, phenolic resin, polyamide resin, polyimide resin, and the like.

In some embodiments, the bank PDL may include a light absorption material or have a light absorber coated thereon, to absorb light introduced from the outside. In an embodiment, for example, the bank PDL may include a carbon-based black pigment. However, the disclosure is not necessarily limited thereto, and the bank PDL may include an opaque metal material, such as chromium (Cr), molybdenum (Mo), any alloy (MoTi) of molybdenum and titanium, tungsten (W), vanadium (V), niobium (Nb), tantalum (Ta), manganese (Mn), cobalt (Co) or nickel (Ni), which has a high absorption rate.

A light emitting layer EML of each sub-pixel SP may be disposed on the anode electrode AE exposed by the bank PDL. The cathode electrode CE may be disposed on the light emitting layer EML. The cathode electrode CE may be disposed throughout all the first to third sub-pixels SP1 to SP3. In an embodiment, for example, the cathode electrode CE may be provided as a common electrode, but the disclosure is not necessarily limited thereto.

The cathode electrode CE may be made of or defined by a metal layer including at least one selected from silver (Ag), magnesium (Mg), aluminum (Al), platinum (Pt), palladium (Pd), gold (Au), nickel (Ni), neodymium (Nd), iridium (Ir) chromium (Cr) or any alloy thereof, and/or a transparent conductive layer including at least one selected from indium tin oxide (ITO), indium zinc oxide (IZO), zinc oxide (ZnO) or indium tin zinc oxide (ITZO). In an embodiment, the cathode electrode CE may be formed as a multi-layer including at least two layers including a metal thin film layer. In an embodiment, for example, the cathode electrode CE may be formed in (or defined by) a triple layer of ITO/Ag/ITO.

The thin film encapsulation layer TFE may be disposed on the display element layer DPL. The thin film encapsulation layer TFE may have a single-layer structure or a multi-layer structure. The thin film encapsulation layer TFE may include an insulating layer covering the light emitting element LD. The thin film encapsulation layer TFE may include at least one inorganic layer and at least one organic layer. In an embodiment, for example, the thin film encapsulation layer TFE may have a structure in which an inorganic layer and an organic layer are alternately stacked. In an embodiment, for example, the thin film encapsulation layer TFE may include a first inorganic layer, an organic disposed on the first inorganic layer, and a second inorganic layer disposed on the organic layer.

A sensing layer TS may be disposed on the thin film encapsulation layer TFE. The sensing layer TS may include a first conductive layer MT1, a second conductive layer MT2, and/or insulating layers INS (or a first insulating layer INS1, a second insulating layer INS2, and/or a third insulating layer INS3).

The first insulating layer INS1 may be disposed on the thin film encapsulation layer TFE. The first insulating layer INS1 may be an inorganic insulating layer including an inorganic material. The inorganic insulating layer may include an inorganic insulating material such as silicon oxide (SiOₓ), silicon nitride (SiNₓ), silicon oxynitride (SiOₓN_{y}), aluminum oxide (AlₓO_{y}), titanium oxide (TiOₓ), tantalum oxide (TaₓO_{y}), hafnium oxide (HfOₓ), or zinc oxide (ZnOₓ). In some embodiments, the first insulating layer INS1 may be omitted, or be configured as an uppermost layer of the thin film encapsulation layer TFE.

The first conductive layer MT1 may be disposed on the first insulating layer INS1. The first conductive layer MT1 may be partially opened not to overlap a light emitting element LD of each sub-pixel SP. In an example, the first conductive layer MT1 may be disposed to overlap the non-emission area NEA at the periphery of the emission area EMA.

The first conductive layer MT1 may include a metal layer or a transparent conductive layer. In an embodiment, for example, the metal layer may include molybdenum, titanium, copper, aluminum, and alloys thereof. The transparent conductive layer may include at least one selected from indium tin oxide (ITO), indium zinc oxide (IZO), zinc oxide (ZnO), indium tin zinc oxide (ITZO), poly(3,4-ethylenedioxythiophene) (PEDOT), and metal nano wires, but the disclosure is not necessarily limited thereto. The first conductive layer MT1 may form a connection electrode connecting sensing electrodes to each other.

The second insulating layer INS2 may be disposed over the first conductive layer MT1. The second insulating layer INS2 may include a same material as the first insulating layer INS1, or include at least one material selected from the materials listed above as the material constituting the first insulating layer INS1.

The second conductive layer MT2 may be disposed on the second insulating layer INS2. The second conductive layer MT2 may be partially opened not to overlap the light emitting element LD of each sub-pixel SP. In an embodiment, for example, the second conductive layer MT2 may be disposed to overlap with the non-emission area NEA at the periphery of the emission area EMA.

The second conductive layer MT2 may include the same material as the first conductive layer MT1, or include at least one material selected from the materials listed above as the material constituting the first conductive layer MT1.

The second conductive layer MT2 may be electrically connected to the first conductive layer MT1 through a contact hole defined or formed through the second insulating layer INS2.

The third insulating layer INS3 may be disposed over the second conductive layer MT2. The third insulating layer INS3 may be an organic insulating layer including an organic material. However, the disclosure is not necessarily limited thereto. In some embodiments, the third insulating layer INS3 may be formed of or defined by an inorganic layer, or have a structure in which an organic layer and an inorganic layer are alternately stacked.

A light blocking layer LBP may be disposed on the display element layer DPL, the thin film encapsulation layer TFE, and/or the sensing layer TS. The light blocking layer LBP may define an opening overlapping (or exposing) the light emitting element LD. In an embodiment, for example, the light blocking layer LBP may be disposed to overlap the non-emission area NEA at the periphery of the emission area EMA.

The light blocking layer LBP may include a light blocking material to prevent light leakage and color mixture. In an embodiment, for example, the light blocking layer LBP may include a black matrix, but the disclosure is not necessarily limited thereto.

A color filter layer CFL may be disposed over the light blocking layer LBP. The color filter layer CFL may include color filters CF1 to CF3 each of which accords with a color of each sub-pixel SP. The color filters CF1 to CF3 which respectively accord with the first to third sub-pixels SP1 to SP3 are disposed, so that a full-color image can be displayed.

The color filter layer CFL may include a first color filter CF1 disposed in the first sub-pixel SP1 to allow light emitted from the first sub-pixel SP1 to be selectively transmitted therethrough, a second color filter CF2 disposed in the second sub-pixel SP2 to allow light emitted from the second sub-pixel SP2 to be selectively transmitted therethrough, and a third color filter CF3 disposed in the third sub-pixel SP3 to allow light emitted from the third sub-pixel SP3 to be selectively transmitted therethrough.

In an embodiment, the first color filter CF1, the second color filter CF2, and the third color filter CF3 may be a red color filter, a green color filter, and a blue color filter, respectively, but the disclosure is not necessarily limited thereto.

The first color filter CF1 may include a color filter material which allows light of a first color (or red) to be selectively transmitted therethrough. In an embodiment, for example, where the first sub-pixel SP1 is a red sub-pixel, the first color filter CF1 may include a red color filter material.

The second color filter CF2 may include a color filter material which allows light of a second color (or green) to be selectively transmitted therethrough. In an embodiment, for example, where the second sub-pixel SP2 is a green sub-pixel, the second color filter CF2 may include a green color filter material.

The third color filter CF3 may include a color filter material which allows light of a third color (or blue) to be selectively transmitted therethrough. In an embodiment, for example, where the third sub-pixel SP3 is a blue sub-pixel, the third color filter CF3 may include a blue color filter material.

An overcoat layer OC may be provided on the color filter layer CFL. The overcoat layer OC may include various materials suitable for protecting lower layers from a foreign matter such as dust or moisture. In an embodiment, for example, the overcoat layer OC may include at least one selected from an inorganic insulating layer and an organic insulating layer. In an embodiment, for example, the overcoat layer OC may include epoxy, but embodiments are not limited thereto.

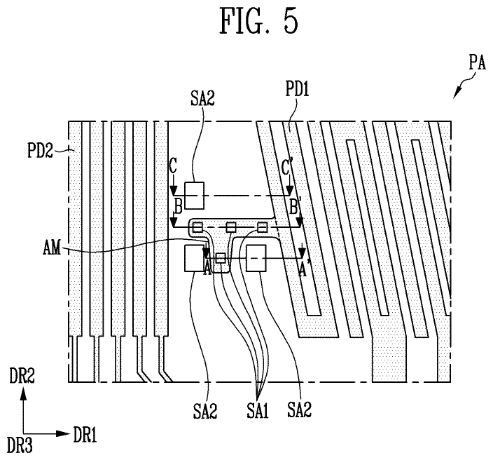

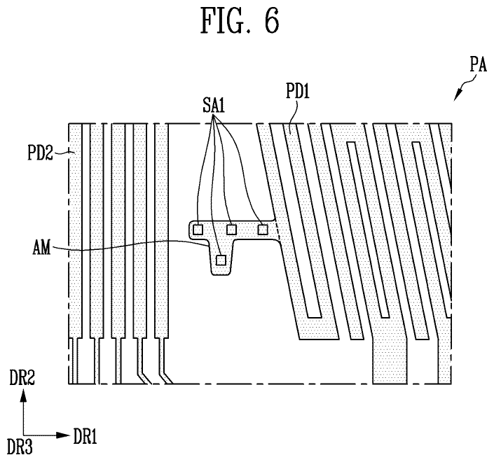

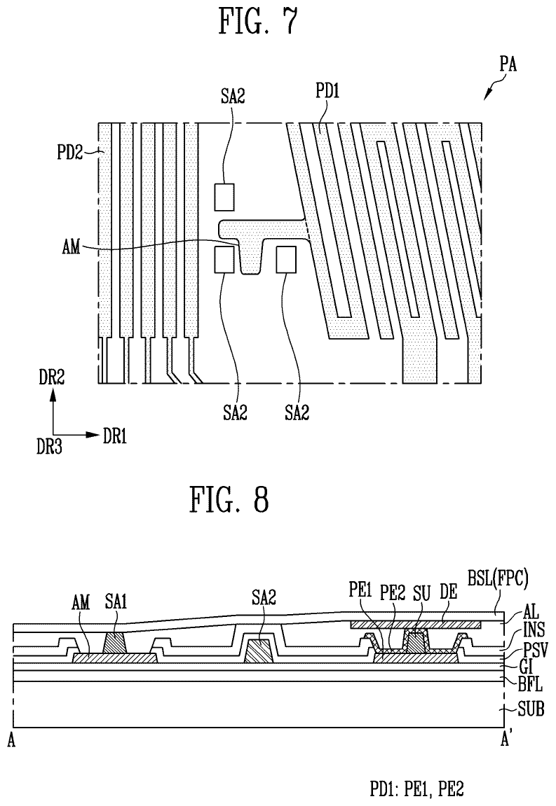

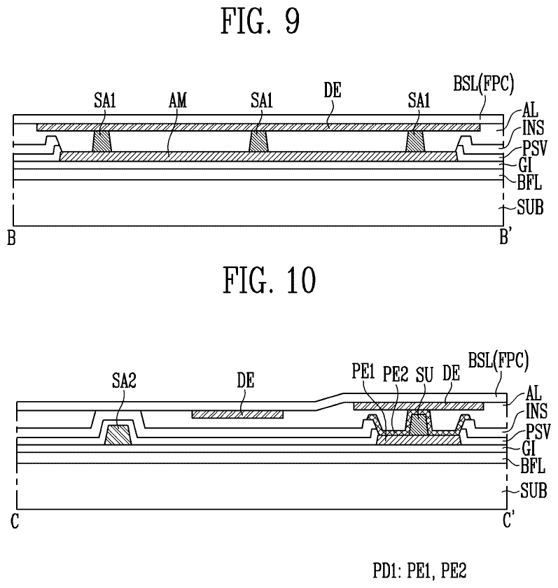

FIGS. 5 to 7 are plan views schematically illustrating a portion of the pad area in an embodiment of the disclosure. FIG. 8 is a sectional view taken along line A-A′ shown in FIG. 5. FIG. 9 is a sectional view taken along line B-B′ shown in FIG. 5. FIG. 10 is a sectional view taken along line C-C′ shown in FIG. 5. Particularly, FIGS. 8 to 10 are sectional views illustrating a structure in which the display panel DP and the driving unit DU are bonded to each other in the pad area PA.

Referring to FIGS. 5 to 10, in an embodiment, the pad area PA may include first pads PD1, second pads PD2, and/or an alignment mark AM. The alignment mark AM may be disposed between the first pads PD1 and the second pads PD2 on a plane or in a plan view, but the disclosure is not necessarily limited thereto. The first pads PD1, the second pads PD2, and/or the alignment mark AM may be arranged along the first direction DR1, but the disclosure is not necessarily limited thereto.

In an embodiment, the first pads PD1 may serve as test pads for resistance measurement after the display panel DP and the driving unit DU are bonded to each other. The second pads PD2 may be dummy pads. In an embodiment, for example, the second pads PD2 may serve as test pads for testing the display panel DP before the display panel DP and the driving unit DU are bonded to each other. The alignment mark AM may be used as a reference for determining an alignment state between the display panel DP and the driving unit DU. However, the uses or functions of the first pads PD1, the second pads PD2, and/or the alignment mark AM are not necessarily limited thereto, and may be variously changed in some embodiments.

In an embodiment, as shown in FIG. 8, the first pads PD1 may include a first pad electrode PE1 and a second pad electrode PE2. The first pad electrode PE1 may be disposed on the gate insulating layer GI. The first pad electrode PE1 may be disposed directly on the gate insulating layer GI. The first pad electrode PE1 may be disposed between the gate insulating layer GI and the passivation layer PSV.

The first pad electrode PE1 may be disposed in a same layer (or defined by a same layer) as the first transistor electrode TE1 and/or the second transistor electrode TE2 shown in FIG. 4. The first pad electrode PE1 may be simultaneously formed with the first transistor electrode TE1 and/or the second transistor electrode TE2 through a same process, but the disclosure is not necessarily limited thereto.

The second pad electrode PE2 may be disposed on the first pad electrode PE1. The second pad electrode PE2 may be electrically connected to the first pad electrode PE1. The second pad electrode PE2 may be at least partially in contact with the first electrode PE1.

The second pad electrode PE2 may be disposed on the insulating layer INS (or the first insulating layer INS1, the second insulating layer INS2, and/or the third insulating layer INS3). The second pad electrode PE2 may be disposed directly on the insulating layer INS (or the first insulating layer INS1, the second insulating layer INS2, and/or the third insulating layer INS3). The second pad electrode PE2 may be disposed on a portion of the first pad electrode PE1 exposed by an opening of the insulating layer INS (or the first insulating layer INS1, the second insulating layer INS2, and/or the third insulating layer INS3).

The second pad electrode PE2 may be disposed in a same layer as the first conductive layer MT1. The second pad electrode PE2 may be simultaneously formed with the first conductive layer MT1 through a same process, but the disclosure is not necessarily limited thereto. In some embodiments, the second pad electrode PE2 may be disposed in the same layer as the second conductive layer MT2. The second pad electrode PE2 may be simultaneously formed with the second conductive layer MT2 through the same process, but the disclosure is not necessarily limited thereto.

The second pad electrode PE2 may be electrically connected to a driving terminal DE. The second pad electrode PE2 may be in contact with the driving terminal DE. The driving terminal DE may be disposed on a base layer BSL of the driving unit (see DU shown in FIG. 1). The base layer BSL may face the substrate SUB. An adhesive layer AL may be disposed between the base layer BSL and the substrate SUB. The adhesive layer AL may be disposed between the driving terminal DE and the second pad electrode PE2. The adhesive layer AL may be interposed at a periphery of an area in which the driving terminal DE and the second pad electrode PE2 are connected to each other to couple the base layer BSL and the substrate SUB to each other. The adhesive layer AL may be a non-conductive film (NCF), but the disclosure is not necessarily limited thereto.

The passivation layer PSV and/or the insulating layer (or the first insulating layer INS1, the second insulating layer INS2, and/or the third insulating layer INS3) may be disposed between the first pad electrode PE1 and the second pad electrode PE2. The passivation layer PSV and/or the insulating layer INS may be provided with an opening exposing the first pad electrode PE1. In an embodiment, the second pads PD2 may have a same sectional structure as the first pads PD1, and therefore, any repetitive detailed descriptions thereof will be omitted.

In an embodiment, a first support unit SU may be disposed between the first pad electrode PE1 and the second pad electrode PE2. The first support unit SU may overlap the first pad electrode PE1 and/or the second pad electrode PE2 in the third direction DR3.

The first support unit SU may be disposed directly on the first pad electrode PE1. The first support unit SU may be disposed on the first pad electrode PE1 exposed by the opening of the passivation layer PSV and/or the insulating layer INS (or the first insulating layer INS1, the second insulating layer INS2, and/or the third insulating layer INS3). The first support unit SU may be partially disposed on (or overlap a portion of) the first pad electrode PE1.

The second pad electrode PE2 may be disposed over the first support unit SU. The second pad electrode PE2 may be disposed directly over the first support unit SU. The second pad electrode PE2 may entirely cover the first support unit SU. In an embodiment, for example, the second pad electrode PE2 may entirely cover top and side surfaces of the first support unit SU. A width of the second pad electrode PE2 in the first direction DR1 may be larger than a width of the first support unit SU in the first direction DR1. The second pad electrode PE2 may cover a position of the first pad electrode PE1 exposed by the first support unit SU.

The first support unit SU may have a shape protruding in the third direction DR3. The second pad electrode PE2 may protrude in the third direction DR3 by the first support unit SU to be in contact with the driving terminal DE. In an embodiment, for example, the base layer BSL of the flexible circuit board FPC may be pressurized, thereby connecting the driving terminal DE to a protruding area of the second pad electrode PE2. The first support unit SU may serve as an elastic body in a process in which the driving DE and the second pad electrode PE2 are directly connected to each other. Accordingly, the display panel DP can be effectively prevented from being damaged in a processing of bonding the driving terminal DE and the second pad electrode PE2 to each other.

The first support unit SU may include an organic material. In an embodiment, for example, the first support unit SU may include at least one selected from acrylic resin, epoxy resin, phenolic resin, polyamide resin, polyimide resin, unsaturated polyester resin, poly-phenylene ether resin, poly-phenylene sulfide resin, and benzocyclobutene resin, but the disclosure is not necessarily limited thereto.

In an embodiment, as described above, the driving terminal DE and the second pad electrode PE2 are directly connected to each other by the first support unit SU, such that a conductive particle (or conductive ball) for electrically connecting the driving terminal DE and the second pad electrode PE2 to each other may be omitted. Accordingly, a short failure or open failure due to the conductive particle can be effectively prevented.

Second support units SA1 may be disposed on the alignment mark AM. Each of the second support units SA1 may overlap the alignment mark AM in the third direction DR3. The second support units SA1 may be spaced apart from each other on a plane.

Each of the second support units SA1 may be disposed on the alignment mark AM. Each of the second support units SA1 may be disposed on the alignment mark AM exposed by the opening of the passivation layer PSV and/or the insulating layer INS (or the first insulating layer INS1, the second insulating layer INS2, and/or the third insulating layer INS3). In an embodiment, at least one of the second support units SA1 may be disposed between the alignment mark AM and the driving terminal DE, but the disclosure is not necessarily limited thereto.

In an embodiment, the second support unit SA1 may function to maintain a bonding gap by compensating for a step difference between the base layer BSL and the substrate SUB (or between the display panel DP and the driving unit DU). In an embodiment, for example, as a step difference occurs in an area in which the pad PD and/or the driving terminal DE are/is not formed in the pad area PA, stress may be concentrated on the corresponding area in bonding. Thus, the step difference is compensated by forming the second support unit SA1 on the alignment mark AM, such that deformation of the display panel DP and the driving unit DU in bonding can be minimized, and stress can be reduced, thereby reducing delamination of an interface (an interface between the display panel DP and the adhesive layer AL and/or an interface between the adhesive layer AL and the driving unit DU).

In an embodiment, the second support unit SA1 may be disposed in a same layer as the first support unit SU. A thickness of the second support unit SA1 in the third direction DR3 may be equal to (or substantially the same as) a thickness of the first support unit SU in the third direction DR3. The second support unit SA1 may include a same material as the first support unit SU. The second support unit SA1 may be simultaneously formed with the first support unit SU through a same process, but the disclosure is not necessarily limited thereto.

The second support unit SA1 may have elasticity. In an embodiment, for example, the second support unit SA1 may effectively prevent the display panel DP from being damaged in a process of bonding the driving terminal DE and the second pad electrode PE2 to each other.

The second support unit SA1 may include an organic material. In an embodiment, for example, the second support unit SA1 may include at least one selected from acrylic resin, epoxy resin, phenolic resin, polyamide resin, polyimide resin, unsaturated polyester resin, poly-phenylene ether resin, poly-phenylene sulfide resin, and benzocyclobutene resin, but the disclosure is not necessarily limited thereto.

A third support unit SA2 may be disposed at the periphery of the alignment mark AM. The third support unit SA2 may not overlap the alignment mark AM in the third direction DR3. In an embodiment, the third support unit SA2 may not overlap the driving terminal DE in the third direction DR3, but the disclosure is not necessarily limited thereto.

The third support unit SA2 may function to maintain a bonding gap by compensating for a step difference between the base layer BSL and the substrate SUB. In an embodiment, for example, as a step difference occurs in an area in which the pad PD and/or the driving terminal DE are/is not formed in the pad area PA, stress may be concentrated on the corresponding area in bonding. Thus, the step difference is compensated by forming the third support unit SA2 at the periphery of the alignment mark AM, so that deformation of the display panel DP and the driving unit DU in bonding can be minimized, and stress can be reduced, thereby reducing delamination of an interface (an interface between the display panel DP and the adhesive layer AL and/or an interface between the adhesive layer AL and the driving unit DU).

In an embodiment, the third support unit SA2 may be disposed in a layer different from the layer in which the first support unit SU and/or the second support unit SA1 are/is disposed. In an embodiment, for example, the third support unit SA2 may be disposed between the gate insulating layer GI and the passivation layer PSV. The third support unit SA2 may be disposed on the gate insulating layer GI. The third support unit SA2 may be disposed directly on the gate insulating layer GI. The passivation layer PSV may be disposed over the third support unit SA2. The passivation layer PSV may be disposed directly over the third support unit SA2. The passivation layer PSV may entirely cover the third support unit SA2. The passivation layer PSV may entirely cover top and side surfaces of the third support unit SA2.

A thickness of the third support unit SA2 in the third direction DR3 may be different from the thickness of the first support unit SU in the third direction DR3 and/or the thickness of the second support unit SA1 in the third direction DR3. In an embodiment, for example, the thickness of the third support unit SA2 in the third direction DR3 may be thicker (or greater) than the thickness of the first support unit SU in the third direction DR3 and/or the thickness of the second support unit SA1 in the third direction DR3.

The third support unit SA2 may have elasticity. In an example, the third support unit SA3 may effectively prevent the display panel DP from being damaged in a process of bonding the driving terminal DE and the second pad electrode PE2 to each other.

The third support unit SA2 may include an organic material. In an embodiment, for example, the third support unit SA2 may include at least one selected from acrylic resin, epoxy resin, phenolic resin, polyamide resin, polyimide resin, unsaturated polyester resin, poly-phenylene ether resin, poly-phenylene sulfide resin, and benzocyclobutene resin, but the disclosure is not necessarily limited thereto. In some embodiments, the third support unit SA2 may be omitted as shown in FIG. 6, or the second support unit SA1 may be omitted as shown in FIG. 7.

In accordance with an embodiment, as described above, the support units SU, SA1, and SA2 are disposed in the pad area PA, so that deformation of the display panel DP and the driving unit DU in bonding can be effectively prevented, and stress can be reduced, thereby reducing delamination of an interface (an interface between the display panel DP and the adhesive layer AL and/or an interface between the adhesive layer AL and the driving unit DU).

In accordance with an embodiment of the disclosure, support units are disposed in a pad area, thereby minimizing or compensating a step difference. Accordingly, deformation of the display panel and the driving unit in bonding can be effectively prevented, and stress can be reduced, thereby reducing interface delamination.

A display device according to an embodiment is applicable to various types of electronic devices. In an embodiment, an electronic device includes the above-described display device and may further include other modules or devices having additional functions in addition to the display device.

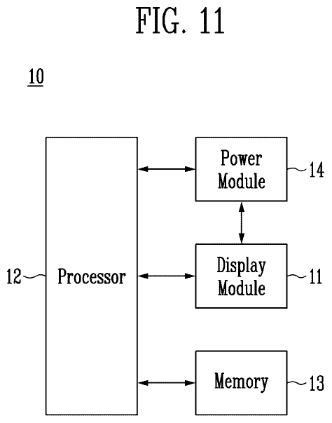

FIG. 11 is a block diagram of an electronic device according to an embodiment. Referring to FIG. 11, an embodiment of the electronic device 10 may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. In an embodiment, for example, the display module 11 is included in the display device, whereas the processor 12, the memory 13, and the power module 14 are not included in the display device and are instead provided separately in the electronic device 10.

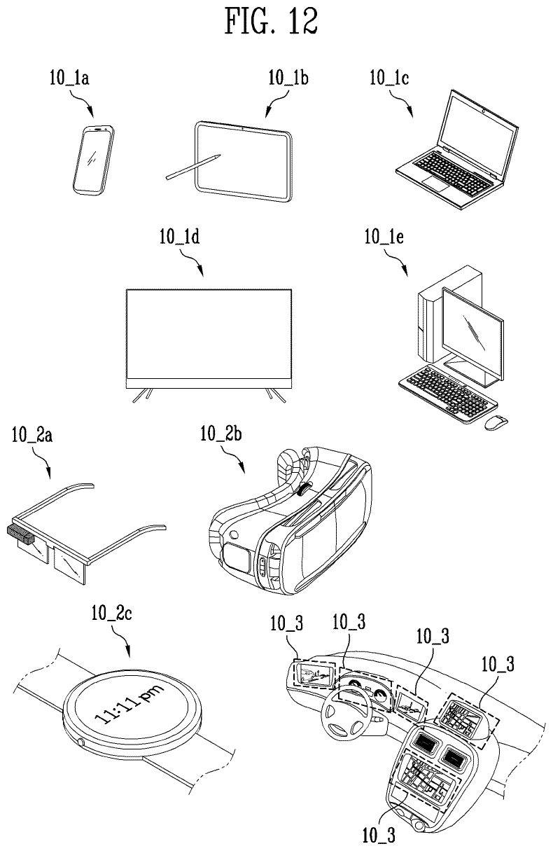

FIG. 12 shows schematic views of various embodiments of an electronic device.

Referring to FIG. 12, various types of electronic device to which an embodiment of a display device is applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, an HMD 10_2b, and a smart watch 10_2c, and an automotive electronic device 10_3 including a display module such as a center information display (CID) disposed at the instrument cluster, the center fascia, and the dashboard of a vehicle, and a room mirror display.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first pad electrode on a substrate in a pad area of the substrate;
a second pad electrode on the first pad electrode;
a first support unit between the first pad electrode and the second pad electrode;
an alignment mark on the substrate in the pad area; and
a second support unit on the alignment mark.

2. The display device of claim 1, wherein the first support unit is disposed in a same layer as the second support unit.

3. The display device of claim 1, wherein a thickness of the first support unit is substantially the same as a thickness of the second support unit.

4. The display device of claim 1, wherein the first support unit includes a same material as the second support unit.

5. The display device of claim 1, wherein each of the first support unit and the second support unit includes an organic material.

6. The display device of claim 1, further comprising:
a driving terminal electrically connected to the second pad electrode.

7. The display device of claim 6, wherein the second pad electrode is in contact with the driving terminal.

8. The display device of claim 6, wherein the second pad electrode is disposed between the first support unit and the driving terminal.

9. The display device of claim 6, further comprising:
an adhesive layer between the second pad electrode and the driving terminal.

10. The display device of claim 6, wherein the second support unit is disposed between the alignment mark and the driving terminal.

11. A display device comprising:
a first pad electrode on a substate in a pad area of the substrate;
a second pad electrode on the first pad electrode;
a first support unit between the first pad electrode and the second pad electrode;
an alignment mark on the substrate in the pad area; and
a third support unit on the substrate at a periphery of the alignment mark.

12. The display device of claim 11, wherein the third support unit does not overlap the alignment mark in a plan view.

13. The display device of claim 11, wherein the first support unit is disposed in a layer different from a layer in which the third support unit is disposed.

14. The display device of claim 11, wherein a thickness of the third support unit is greater than a thickness of the first support unit.

15. The display device of claim 11, wherein each of the third support unit and the first support unit includes an organic material.

16. The display device of claim 11, further comprising:
a driving terminal electrically connected to the second pad electrode.

17. The display device of claim 16, wherein the second pad electrode is in contact with the driving terminal.

18. The display device of claim 16, wherein the second pad electrode is disposed between the first support unit and the driving terminal.

19. The display device of claim 16, wherein the third support unit does not overlap the driving terminal in a plan view.

20. An electronic device comprising:
a processor which provides input image data; and
a display device which displays an image based on the input image data,
wherein the display device comprises:
a first pad electrode on a substrate in a pad area of the substrate;
a second pad electrode on the first pad electrode;
a first support unit between the first pad electrode and the second pad electrode;
an alignment mark on the substrate in the pad area; and
a second support unit on the alignment mark.
